(19) United States
(12) Patent Application Publication
(10) Pub. No.: US 2012/0012893 A1
(43) Pub. Date: Jan. 19, 2012

(54) SEMICONDUCTOR TRANSISTOR AND METHOD OF MANUFACTURING THE SAME

(75) Inventor: Kazushi NAKAZAWA, Toyama (JP)

(73) Assignee: PANASONIC CORPORATION, Osaka (JP)

(21) Appl. No.: 13/177,913

(22) Filed: Jul. 7, 2011

(30) Foreign Application Priority Data
Jul. 16, 2010 (JP) 2010-162311

(51) Int. Cl. H01L 29/812; H01L 21/338; B82Y 99/00

(52) U.S. Cl. 257/192; 438/172; 977/755; 257/E29.315; 257/E21.403

(57) ABSTRACT

To provide a semiconductor transistor without variation in threshold voltage of an FET and a method of manufacturing the semiconductor transistor, the semiconductor transistor includes: a substrate; a first compound semiconductor layer formed above the substrate; a second compound semiconductor layer formed on the first compound semiconductor layer and having a bandgap larger than a bandgap of the first compound semiconductor layer; an oxygen-doped region formed by doping at least part of the second compound semiconductor layer with oxygen; a third compound semiconductor layer formed on the second compound semiconductor layer; a source electrode electrically connected to the first compound semiconductor layer; a drain electrode electrically connected to the first compound semiconductor layer; and a gate electrode formed on and in contact with the oxygen-doped region.

### BACKGROUND OF THE INVENTION

(1) Field of the Invention

The present invention relates to a semiconductor transistor used as, for example, a radio frequency (RF) element and a method of manufacturing the same.

(2) Description of the Related Arts

At present, a heterojunction field effect transistor (FET) using GaAs is used for an RF element used for a cellular phone or the like. In addition, recently, an integration of this FET and a heterojunction bipolar transistor (HBT) on the same substrate has been actively developed.

In the case of the GaAs FET used as a switching device, its response characteristics are important. Generally, there is a high-density trap level (surface level) on the surface of the semiconductor, and this trap level catches a carrier. For this reason, when the carrier is captured by the trap level during high-speed switching, the GaAs FET cannot follow the switching, thus causing deterioration in response characteristics.

A technique for reducing such influence of the surface level is providing a distance between a semiconductor surface beside the gate electrode and a channel (For example, see Patent Reference 1: Japanese Unexamined Patent Application Publication No. 2000-12563). For example, the technique is represented by: an embedded gate electrode structure in which the gate electrode is embedded in the semiconductor using solid-phase diffusion, or a recess structure in which a recess is formed in a semiconductor layer under the gate electrode. Of these, the embedded gate electrode structure can be formed by solid-phase diffusing a gate metal by annealing processing. This is an easy technique because it can be realized without increasing the number of processes including recess etching. In addition, the technique also has an advantage in view of process costs.

### SUMMARY OF THE INVENTION

FIG. 6 is a cross-sectional view showing a configuration of a semiconductor transistor 600 according to a conventional technique. The semiconductor transistor 600 has a multilayer structure in which: a buffer layer 602 including an undoped GaAs, a GaAs layer 603 that is to be a channel layer, a first AlGaAs layer 604, a second AlGaAs layer 605, and a GaAs layer 606 are serially formed on a substrate 601. In addition, on the surface of the GaAs layer 606, a source electrode 607, a drain electrode 609, and an embedded gate electrode 608 are formed. Under the source electrode 607 and the drain electrode 609, a low resistance region 610 is formed.

In the case of the embedded gate electrode structure as described above, when forming the gate electrode 608 using solid phase diffusion, variation is caused in a diffusion depth of the gate metal. In addition, although the distribution can be calculated using a diffusion equation, it is difficult to shape the distribution in a stepped pattern due to its spread. Thus, according to the invention disclosed in Patent Reference 1, as shown in FIG. 6, an AlGaAs barrier layer for diffusing Pt that is to be the gate metal has a two-layer structure made up of the first AlGaAs layer 604 and the second AlGaAs layer 605 that have diffusion coefficients different from each other. Here, the diffusion of Pt that is to be the gate metal is less promoted in the first AlGaAs layer 604 having a higher Al composition ratio than in the second AlGaAs 605 having a lower Al composition. Using the characteristics, reduction in the variation in diffusion depth is attempted by suppressing the diffusion of Pt in first AlGaAs layer 604 having a higher Al composition ratio.

However, in practice, in the configuration shown in FIG. 6, which attempts to control the depth of diffusion of the gate electrode using the difference in diffusion coefficient, the metal is diffused into the semiconductor layer in which the metal is less likely to be diffused. Thus, there is a problem of insufficient control of diffusion depth, thus causing variation in threshold voltage of the FET.

The object of the present invention, in view of the problem, is to provide a semiconductor transistor without variation in the threshold voltage of the FET and the method of manufacturing the semiconductor transistor.

To achieve the object above, a semiconductor transistor according to an aspect of the present invention includes: a substrate; a first compound semiconductor layer formed above the substrate; a second compound semiconductor layer formed on the first compound semiconductor layer and having a bandgap larger than a bandgap of the first compound semiconductor layer; an oxygen-doped region formed by doping at least part of the second compound semiconductor layer with oxygen; a third compound semiconductor layer formed on the second compound semiconductor layer; a source electrode electrically connected to the first compound semiconductor layer; a drain electrode electrically connected to the first compound semiconductor layer; and a gate electrode formed on and in contact with the oxygen-doped region.

Since this configuration allows suppressing diffusion of the gate metal due to the oxygen-doped region, it is possible to keep the diffusion of the gate metal at a constant depth, thus making it possible to provide a semiconductor transistor without variation in threshold voltage of the FET.

Here, preferably, the source electrode and the drain electrode are formed on the third compound semiconductor layer, and the second compound semiconductor layer and the third compound semiconductor layer include, under the source electrode and the drain electrode, a low resistance region to which an impurity is added, and the source electrode and the drain electrode are electrically connected to the first compound semiconductor layer via the low resistance region.

With this configuration, it is possible to manufacture a semiconductor transistor without being influenced by increase in series resistance due to the oxygen-doped region.

Here, preferably, the second compound semiconductor layer and the third compound semiconductor layer include a recess formed to reach at least the second compound semiconductor layer from a surface of the third compound semiconductor layer, and the source electrode and the drain electrode are formed in contact with at least one of a bottom surface and a lateral surface of the recess.

With this configuration, it is possible to manufacture a semiconductor transistor without being influenced by increase in series resistance due to the oxygen-doped region, as with the case of forming a low resistance region.

Here, preferably, the second compound semiconductor layer includes AlₓGa₁₋ₓAs (0<x≦1).

Here, preferably, the oxygen-doped region has a thickness of 5 nm or less.

Oxygen forms a deep level and thus has a possibility of having negative influence on the transient response characteristics when film thickness increases in the barrier layer; however, according to this configuration, it is possible to provide a semiconductor transistor without negative influence on the transient response characteristics.

Here, preferably, the oxygen-doped region is a semiconductor layer.

Here, preferably, a concentration of oxygen introduced into the oxygen-doped region is 5×10¹⁶ cm⁻³ or more.

Here, preferably, the gate electrode includes, at least partially, Pt or Pd.

In addition, a method of manufacturing a semiconductor transistor according to an aspect of the present invention includes: forming, above a substrate, a first compound semiconductor layer and a second compound semiconductor layer that has a bandgap larger than a bandgap of the first compound semiconductor layer; forming an oxygen-doped region by doping at least part of the second compound semiconductor layer with oxygen; forming a third compound semiconductor layer on the second compound semiconductor layer; forming a source electrode and a drain electrode that are electrically connected to the first compound semiconductor layer; forming a gate electrode on a surface of the third compound semiconductor layer located on the oxygen-doped region; and diffusing, into the third compound semiconductor layer, a material for forming the gate electrode.

Since this configuration allows suppressing diffusion of the gate metal due to the oxygen-doped region, it is possible to keep the diffusion of the gate metal at a constant depth, thus making it possible to provide a semiconductor transistor without variation in threshold voltage of the FET.

Here, preferably, the method further includes forming a low resistance region to which an impurity is added, prior to the forming of a source electrode and a drain electrode, in the second compound semiconductor layer and the third compound semiconductor layer, under a position at which each of the source electrode and the drain electrode is formed.

With this configuration, it is possible to manufacture a semiconductor transistor without being influenced by increase in series resistance due to the oxygen-doped region.

Here, preferably, the method further includes forming a recess, prior to the forming of a source electrode and a drain electrode, below a position at which each of the source electrode and the drain electrode is formed, the recess reaching at least the second compound semiconductor layer from a surface of the third compound semiconductor.

With this configuration, it is possible to manufacture a semiconductor transistor without being influenced by increase in series resistance due to the oxygen-doped region, as with the case of forming a low resistance region.

According to an implementation of the present invention, it is possible to provide a semiconductor transistor without variation in the threshold voltage of the FET and the method of manufacturing the semiconductor transistor.

### FURTHER INFORMATION ABOUT TECHNICAL BACKGROUND TO THIS APPLICATION

The disclosure of Japanese Patent Application No. 2010-162311 filed on Jul. 16, 2010 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings which illustrate a specific embodiment of the invention. In the Drawings:

FIG. 1 is a cross-sectional view showing a configuration of a semiconductor transistor according to a first embodiment of the present invention;

FIG. 2 is a diagram showing a result of an Auger analysis indicating a diffusion depth of Pt, according to the first embodiment of the present invention;

FIG. 3 is a cross-sectional view showing a configuration of a semiconductor transistor according to a variation of the first embodiment of the present invention;

FIG. 4 is a cross-sectional view showing a configuration of a semiconductor transistor according to a second embodiment of the present invention;

FIG. 5A is a cross-sectional view showing a method of manufacturing the semiconductor transistor according to the second embodiment of the present invention;

FIG. 5B is a cross-sectional view showing the method of manufacturing the semiconductor transistor according to the second embodiment of the present invention;

FIG. 5C is a cross-sectional view showing the method of manufacturing the semiconductor transistor according to the second embodiment of the present invention;

FIG. 5D is a cross-sectional view showing the method of manufacturing the semiconductor transistor according to the second embodiment of the present invention;

FIG. 5E is a cross-sectional view showing the method of manufacturing the semiconductor transistor according to the second embodiment of the present invention;

FIG. 5F is a cross-sectional view showing the method of manufacturing the semiconductor transistor according to the second embodiment of the present invention; and

FIG. 6 is a cross-sectional view showing a configuration of a semiconductor transistor according to a conventional technique.

### DESCRIPTION OF THE PREFERRED EMBODIMENTS

Hereinafter, embodiments of the present invention will be described with reference to the drawings. Note that the present invention will be described with reference to the embodiments and attached drawings exclusively for the purpose of illustration, and the present invention is not limited to these embodiments and drawings.

### First Embodiment

A semiconductor transistor according to the present embodiment includes: a substrate; a first compound semiconductor layer formed above the substrate; a second compound semiconductor layer formed on the first compound semiconductor layer and having a bandgap larger than a bandgap of the first compound semiconductor layer; an oxygen-doped region formed by doping at least part of the second compound semiconductor layer with oxygen; a third compound semiconductor layer formed on the second compound semiconductor layer; a source electrode electrically connected to the first compound semiconductor layer; a drain electrode electrically connected to the first compound semiconductor layer; and a gate electrode formed on and in contact with the oxygen-doped region. Since this configuration allows suppressing diffusion of the gate metal due to the oxygen-doped region, it is possible to keep the diffusion of the gate metal at a constant depth, thus making it possible to provide a semiconductor transistor without variation in threshold voltage of the FET.

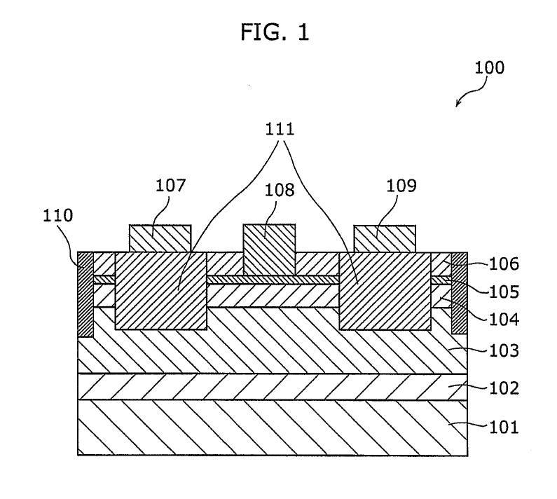

FIG. 1 is a cross-sectional view showing a configuration of a semiconductor transistor 100 according to a first embodiment of the present invention. As shown in FIG. 1, the semiconductor transistor 100 according to the first embodiment has a multilayer structure in which, on a GaAs substrate including GaAs, a buffer layer 102 including undoped GaAs, a GaAs layer 103 that is to be a channel layer, an n-type AlₓGa₁₋ₓAs (AlGaAs) layer 104 that is to be a barrier layer, an oxygen-doped AlₓGa₁₋ₓAs (AlGaAs) layer 105 that is to be a barrier layer, and an undoped AlₓGa₁₋ₓAs (AlGaAs) layer 106 that is to be a barrier layer are serially formed. Here, being undoped means a state of not being intentionally doped during epitaxial growth. Note that the film thickness or layer structure is not limited to this. In addition, hereinafter, AlₓGa₁₋ₓAs is also described as AlGaAs by abbreviating the description of an Al composition ratio x.

Each of the n-type AlGaAs layer 104, the oxygen-doped AlGaAs layer 105, and the undoped AlGaAs layer 106 has a larger bandgap than a bandgap of the GaAs layer 103. In addition, in part of the GaAs layer 103, the n-type AlGaAs layer 104, the oxygen-doped AlGaAs layer 105, the undoped AlGaAs layer 106, a low resistance region 111 formed by ion-doping Si which is an impurity for providing n-type characteristics, from a surface of the undoped AlGaAs layer 106 to a predetermined depth in the GaAs layer 103. In addition, on the surface of the undoped AlGaAs layer 106, a source electrode 107 and a drain electrode 109 are formed each of which has a stacking structure of AuGe, Ni, and Au, so as to be electrically connected to the low resistance region 111. Furthermore, a gate electrode 108 is formed of Pt, in contact with the oxygen-doped AlGaAs layer 105. Here, the GaAs layer 103 corresponds to the first compound semiconductor layer according to the present invention, the n-type AlGaAs layer 104 corresponds to the second compound semiconductor layer according to the present invention, and the undoped AlGaAs layer 106 corresponds to the third compound semiconductor layer according to the present invention.

In addition, an element separation region 110 whose resistance is increased by ion-doping, for example, B is formed, to thereby electrically insulate one semiconductor transistor 100 from another element.

An advantageous feature of the first embodiment is that a layer is formed by doping, with oxygen, the AlGaAs layer that is to be the barrier layer. In other words, the oxygen-doped AlGaAs layer 105 is formed between the n-type AlGaAs layer 104 and the undoped AlGaAs layer 106. In addition, the gate electrode 108 has an embedded gate structure having a lower part in contact with the oxygen-doped AlGaAs layer 105. This embedded gate structure allows separating a semiconductor surface, that is, a surface of the undoped AlGaAs layer 106 from a channel of the FET, thus allowing reduction in influences of the surface level on the channel. This allows realizing a transistor having sufficient transient response characteristics.

Hereinafter, an example of the method of manufacturing the semiconductor transistor 100 configured as above will be described. In the semiconductor transistor 100, for example, by Metal Organic Chemical Vapor Deposition (MOVPE) method, the buffer layer 102 of 800 nm including undoped GaAs, the GaAs layer 103 of 20 nm, the n-type AlGaAs layer 104 of 20 nm, the oxygen-doped AlGaAs layer 105 of 5 nm, and the undoped AlGaAs layer 106 of 20 nm are epitaxially grown serially on a substrate 101 including GaAs.

Note that the film thickness or layer structure is not limited to this. For example, the GaAs layer 103 that is to be the channel layer may also have a stacking structure of InGaAs and GaAs layers, and may also include an AlGaAs layer.

An impurity for providing n-type characteristics to the n-type AlₓGa₁₋ₓAs layer 104 is, for example, Si, and has a concentration of 1 ×10¹⁸ cm⁻³. The concentration of the impurity is not limited to this and may vary in a layer thickness direction.

The n-type AlₓGa₁₋ₓAs layer 104 that is to be the barrier layer, the oxygen-doped AlₓGa₁₋ₓAs layer 105, and the undoped AlₓGa₁₋ₓAs layer 106 have an Al composition ratio of, for example, x=0.2. Note that the Al composition ratio x is not limited to this, and the Al composition ratios x of the three layers need not necessarily be matched. According to the present embodiment, the AlGaAs layer has been shown as an example of the barrier layer, but the barrier layer may also be another layer such as an InGaP layer or an InAlAs layer having a larger bandgap than the GaAs layer.

It is preferable that the oxygen-doped AlGaAs layer 105 have an oxygen concentration of 5×10¹⁶ cm⁻³ or more. In addition, the film thickness thereof should preferably be 5 nm or less. This is because oxygen forms a deep level and thus has a possibility of having negative influences on the transient response characteristics when the film thickness increases in the barrier layer.

Next, a mask is selectively formed on the surface of the undoped AlGaAs layer 106, and subsequently, for example, Si is ion-doped, to form the low resistance region 111. This allows preventing increase in series resistance due to the oxygen-doped AlGaAs layer 105.

Next, by ion-doping B, for example, the element separation region 110 is formed.

Subsequently, the source electrode 107 and the drain electrode 109 including, for example, AuGe/Ni/Au are formed on the low resistance region 111 using an electron beam evaporation technique, a lift-off technique, and subsequently, ohmic sintering processing.

Next, by the electron beam evaporation technique and the lift-off technique, the gate electrode 108 including Pt, for example, is formed. Here, Pt may be Pd, or the gate electrode 108 may have a stacking structure of Pt/Ti/Pt/Au or the like, for example.

Subsequently, Pt is diffused within the undoped AlGaAs layer 106 by heat treatment. Since the solid-phase diffusion of Pt is suppressed when reaching the oxygen-doped AlGaAs layer 105, it is possible to form the gate electrode 108 such that the lower part of the gate electrode 108 is in contact with the oxygen-doped AlGaAs layer 105 without variation. With this, it is possible to manufacture a semiconductor transistor 100 (FET) having an embedded gate structure.

Thus, since the diffusion of Pt does not progress within the oxygen-doped AlGaAs layer 105, it is possible to control the diffusion depth of Pt. Generally, it is difficult to control the depth of the solid-phase diffusion, and the distribution cannot be shaped in a stepped pattern due to its spread because the distribution is shaped in accordance with a complementary error function. However, since the structure according to the present embodiment has the oxygen-doped AlGaAs layer 105 which suppresses the diffusion of Pt, it is possible to form the structure by controlling the depth of the diffusion with sufficient reproducibility.

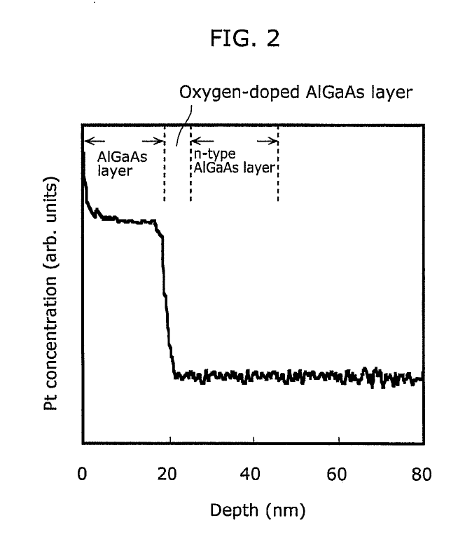

FIG. 2 is a diagram showing a result of an Auger analysis which shows the diffusion depth of Pt. FIG. 2 shows that the concentration of Pt is high in the undoped AlGaAs layer 106 but is low in the n-type AlGaAs layer 104. In other words, it is possible to recognize that the diffusion of Pt does not progress into the oxygen doped AlGaAs layer between the undoped AlGaAs layer 106 and the n-type AlGaAs layer 104, and that the distribution is controlled in a stepped pattern.

Here, the threshold voltage of the semiconductor transistor 100 (FET) is represented by:

Vp=φ_{b}−ΔEc−(qnₛd)/ε (V) (Expression 1)

Here, φ_{b} is a height of a Schottky barrier, and ΔEc is a band offset in a conductor in the GaAs layer 103 and the n-type AlGaAs layer 104, q is a charge amount of electrons, nₛ is a sheet carrier density of the channel, d is a distance between the channel and a lower part of the gate electrode 108, and ε is a permittivity of the AlGaAs barrier layer.

According to (Expression 1), since the threshold voltage of the semiconductor transistor 100 (FET) depends on the distance between the channel and the lower part of the gate electrode 108, the threshold voltage fluctuates when the diffusion depth of the gate metal changes and the distance between the channel and the lower part of the gate electrode 108 accordingly changes. In other words, controlling the diffusion depth of the gate metal is very important for controlling variation in electrical characteristics of the FET.

Since in the present configuration, the diffusion of Pt is stopped by the oxygen-doped AlGaAs layer 105, it is possible to keep a constant distance between the channel and lower part of the gate electrode 108, thus allowing manufacturing without variation in the threshold voltage of the FET. In other words, by forming, in the barrier layer, the embedded gate structure including the oxygen-doped AlGaAs layer, it is possible to realize an FET having high transient response characteristics without variation in threshold voltage.

### First Variation of First Embodiment

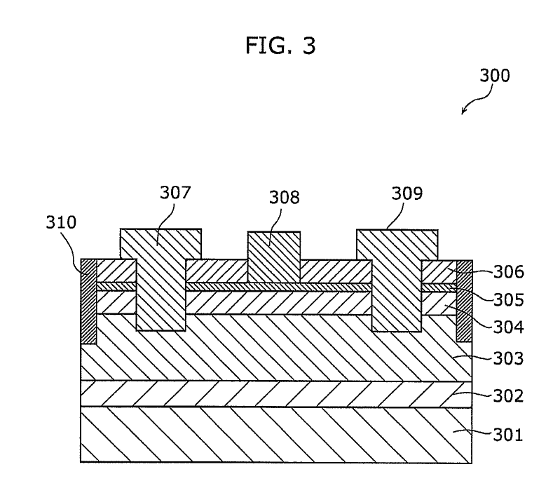

FIG. 3 is a cross-sectional view showing a configuration of a semiconductor transistor according to a variation of the first embodiment of the present invention. As shown in FIG. 3, a semiconductor transistor 300 has a multilayer structure in which, as with the semiconductor transistor 100 shown in FIG. 1, the buffer layer 302 including undoped GaAs, the GaAs layer 303 that is to be a channel layer, the n-type AlₓGa₁₋ₓAs (AlGaAs) layer 304 that is to be a barrier layer, the oxygen doped AlₓGa₁₋ₓAs (AlGaAs) layer 305 that is to be a barrier layer, and the undoped AlₓGa₁₋ₓAs (AlGaAs) layer 306 that is to be a barrier layer are serially formed on a substrate 301 including GaAs. In addition, the source electrode 307, the gate electrode 308, and the drain electrode 309 are formed from the surface of the undoped AlGaAs layer 306 to a predetermined depth. In addition, by the element separation region 310, one semiconductor transistor 300 is electrically isolated from another element. Here, the GaAs layer 303 corresponds to the first compound semiconductor layer according to the present invention, the n-type AlGaAs layer 304 corresponds to the second compound semiconductor layer according to the present invention, and the undoped AlGaAs layer 306 corresponds to the third compound semiconductor layer according to the present invention.

The semiconductor transistor 300 according to the present variation is different from the semiconductor transistor 100 according to the first embodiment in that: as shown in FIG. 3, the semiconductor transistor 300 according to the present variation, instead of having a low resistance region below the source electrode and the drain electrode, includes, in the semiconductor transistor 300, a recess which reaches the GaAs layer 303 from the surface of the undoped AlGaAs layer 306, and the source electrode 307 or the drain electrode 309 is formed in the recess. By forming the source electrode 307 and the drain electrode 309 in contact with the GaAs layer 303 that is to be the channel layer, it is possible to manufacture an FET, as with the case of forming the low resistance region, without being influenced by increase in series resistance due to the oxygen-doped AlGaAs layer 305.

Hereinafter, an example of the method of manufacturing the semiconductor transistor 300 configured as above will be described. In the semiconductor transistor 300, for example, by Metal Organic Chemical Vapor Deposition (MOVPE) method, the buffer layer 302 of 800 nm including undoped GaAs, the GaAs layer 303 of 20 nm, the n-type AlGaAs layer 304 of 20 nm, the oxygen-doped AlGaAs layer 305 of 5 nm, and the undoped AlGaAs layer 306 of 20 nm are epitaxially grown serially on a substrate 301 including GaAs.

Note that the film thickness or layer structure is not limited to this, but the oxygen-doped AlGaAs layer 305 should preferably be 5 nm or less. In addition, the barrier layer is not limited to the AlGaAs layer but may be another layer such as an InGaP layer or an InAlAs layer having a larger bandgap than the GaAs layer.

Next, a mask is selectively formed on the surface of the undoped AlGaAs layer 306, and subsequently the recess is formed by, for example, dry etching. The bottom surface of the recess only needs to reach at least the n-type AlGaAs layer 304, but should preferably reach the GaAs layer 303.

Next, by ion-doping B, for example, the element separation region 310 is formed. Subsequently, the source electrode 307 and the drain electrode 309 including, for example, AuGe/Ni/Au are formed to cover the recess using an electron beam evaporation technique, a lift-off technique, and subsequently, ohmic sintering processing. Here, a stack of metals AuGe/Ni/Au is in contact with a bottom surface and a lateral surface of the recess, and has a lateral surface in contact with the channel.

Next, by the electron beam evaporation technique and the lift-off technique, the gate electrode 308 including Pt, for example, is formed. Here, Pt may be Pd, or the gate electrode 308 may be a stacking structure of Pt/Ti/Pt/Au or the like, for example.

Subsequently, by diffusing Pt within the undoped AlGaAs layer 306 by heat treatment, the lower part of the gate electrode 308 is formed in contact with the oxygen-doped AlGaAs layer 305. With this, it is possible to manufacture the semiconductor transistor 300 (FET) having an embedded gate structure. According to the present variation, because the GaAs layer 303 that is to be the channel layer is formed in contact with the source electrode 307 and the drain electrode 309, it is possible to manufacture an FET without increase in ON resistance. With this, it is possible to realize, without variation in threshold voltage, an FET having satisfactory transient response characteristics as with the first embodiment.

### Second Embodiment

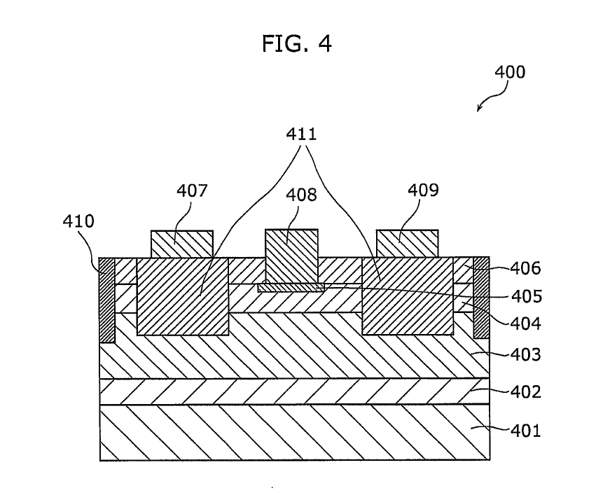

FIG. 4 is a cross-sectional view showing a configuration of a semiconductor transistor 400 according to a second embodiment of the present invention. As shown in FIG. 4, in the semiconductor transistor 400 according to the second embodiment, the buffer layer 402 having a film thickness of 800 nm and including undoped GaAs; the GaAs layer 403 which has a film thickness of 20 nm and is to be the channel layer; the n-type AlGaAs layer 404 which has a film thickness of 20 nm and is to be a barrier layer; and the undoped AlGaAs layer 406 which has a film thickness of 20 nm and is to be a barrier layer are serially formed on a substrate 401 including GaAs. In the n-type AlGaAs layer 404, an oxygen-doped region 405 is formed by doping with oxygen. Note that the film thickness or layer structure is not limited to this. Here, the GaAs layer 403 corresponds to the first compound semiconductor layer according to the present invention, the n-type AlGaAs layer 404 corresponds to the second compound semiconductor layer according to the present invention, and the undoped AlGaAs layer 406 corresponds to the third compound semiconductor layer according to the present invention.

In part of the GaAs layer 403, the n-type AlGaAs layer 404, and the undoped AlGaAs layer 406, a low resistance region 411 is formed by ion-doping Si which is an impurity for providing n-type characteristics, from a surface of the undoped AlGaAs layer 406 to a predetermined depth in the GaAs layer 403. In addition, the source electrode 407 and the drain electrode 409 having a stacking structure of AuGe, Ni, and Au are formed in contact with the low resistance region 411. In addition, the gate electrode 408 including Pt is formed to have a lower part in contact with the oxygen-doped region 405.

In addition, an element separation region 410 whose resistance is increased by ion-doping, for example, B is formed, to thereby electrically insulate the semiconductor transistor 400 from another element.

As a feature of the second embodiment, the oxygen-doped region 405 is formed in the n-type AlGaAs layer 404 that is to be a barrier layer located immediately beneath the gate electrode 408, and the gate electrode 408 has an embedded gate structure having a lower part in contact with the oxygen-doped region 405. This embedded gate structure allows separating a semiconductor surface, that is, a surface of the undoped AlGaAs layer 406 from a channel of the FET, thus allowing reducing an influence of the surface level on the channel. With this, it is possible to realize the semiconductor transistor 400 having satisfactory transient response characteristics. In addition, since the oxygen-doped region 405 is formed immediately beneath the gate electrode 408, it is possible to realize a semiconductor transistor having satisfactory characteristics, without increasing resistance of the source electrode 407 and the drain electrode 409.

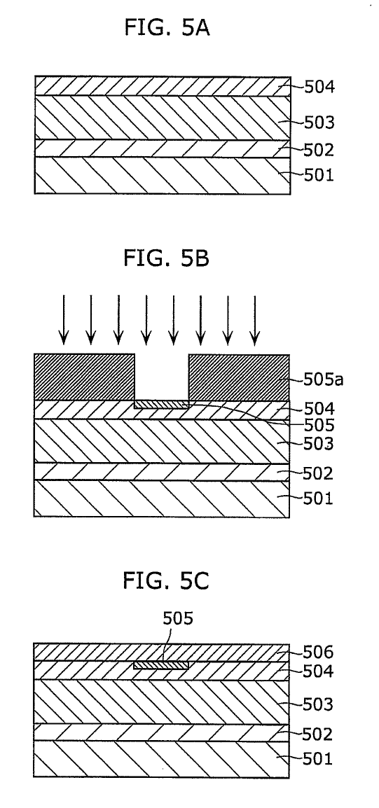

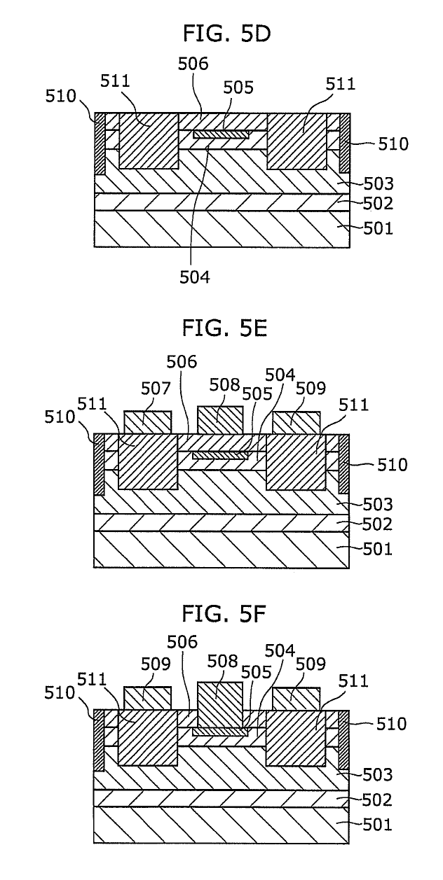

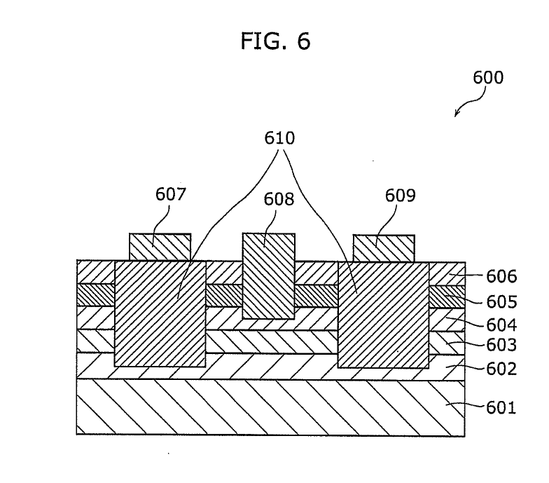

Hereinafter, an example of the method of manufacturing the semiconductor transistor 400 configured as above will be described. FIGS. 5A to 5F are cross-sectional views showing a method of manufacturing the semiconductor transistor 400 according to the second embodiment of the present invention.

First, as shown in FIG. 5A, for example, by Metal Organic Chemical Vapor Deposition (MOVPE) method, a buffer layer 502 of 800 nm including undoped GaAs, the GaAs layer 503 of 20 nm, and the n-type AlGaAs layer 504 of 20 nm are epitaxially grown serially on a substrate 501 including GaAs.

Note that the film thickness or layer structure is not limited to this. For example, the GaAs layer 503 that is to be the channel layer may also have a stacking structure of InGaAs and GaAs layers, and may also include an AlGaAs layer.

An impurity for providing n-type characteristics to the AlₓGa₁₋ₓAs layer 504 is, for example, Si, and has a concentration of 1 ×10¹⁸ cm⁻³. The concentration of the impurity is not limited to this and may vary in a layer thickness direction. The Al composition ratio is, for example, x=0.2. Note that the Al composition ratio x is not limited to this. Note that, according to the present embodiment, the AlGaAs layer has been shown as an example of the barrier layer, but the barrier layer may also be another layer such as an InGaP layer or an InAlAs layer having a larger bandgap than the GaAs layer.

Next, as shown in FIG. 5B, after selectively forming a mask 505a on a surface of the n-type AlGaAs layer 504 using resist or the like, the oxygen-doped region 505 is selectively formed on the surface of the n-type AlGaAs layer 504 by performing, for example, oxygen plasma processing (FIG. 5B).

Subsequently, as shown in FIG. 5C, after removing the mask 505a, the undoped AlGaAs layer 506 that is to be a barrier layer having a film thickness of 20 nm is epitaxially re-grown (FIG. 5C).

After selectively forming a mask (not shown) on the surface of the undoped AlGaAs layer 506, for example, Si is ion-doped so as to form a low resistance region 511 as shown in FIG. 5D. This allows preventing increase in series resistance due to the oxygen-doped AlGaAs layer 105.

Next, the element separation region 510 is formed by ion-doping B, for example (FIG. 5D).

Subsequently, the source electrode 507 and the drain electrode 509 including AuGe/Ni/Au, for example, are formed on the low resistance region 511 using the electron beam evaporation technique, the lift-off technique, and subsequently, ohmic sintering processing.

Next, by the electron beam evaporation technique and the lift-off technique, the gate electrode 508 including Pt, for example, is formed (FIG. 5E). Here, Pt may be Pd, or the gate electrode 508 may have a stacking structure of, for example, Pt/Ti/Pt/Au or the like.

Subsequently, as shown in FIG. 5F, Pt is diffused within the undoped AlGaAs layer 506 by heat treatment (FIG. 5F). Since the solid-phase diffusion of Pt stops when reaching the oxygen-doped AlGaAs layer 505, it is possible to form the gate electrode 508 such that the lower part of the gate electrode 508 is in contact with the oxygen-doped AlGaAs layer 505 without variation. With this, it is possible to manufacture the semiconductor transistor 400 (FET) having an embedded gate structure.

Note that in the present embodiment, it is not essential to form the low resistance region 511, and as shown in the variation of the first embodiment, for example, after forming a recess whose lower portion reaches the GaAs layer 503, the source electrode 507 and the drain electrode 509 may be formed to cover the recess. In addition, after selectively forming the low resistance layer on the undoped AlGaAs layer 506, the source electrode 507 and the drain electrode 509 may be formed on the low resistance layer.

Thus, since the diffusion of Pt does not progress within the oxygen-doped AlGaAs layer 505, it is possible to arbitrarily control the diffusion depth of Pt. In addition, in the configuration, the oxygen-doped region 505 is formed only within the n-type AlGaAs layer 504 that is to be the barrier layer immediately beneath the gate electrode 508, thus realizing the semiconductor transistor 400 (FET) having satisfactory transient response characteristics and little variation, without giving influence to the electrical characteristics such as On-resistance.

Note that the manufacturing method using the re-growth of the AlGaAs layer has been described in the present embodiment, but the manufacturing method is not limited to this, and another method may be used.

The threshold voltage of the FET, as shown in (Expression 1), depends on the distance between the channel and the lower part of the gate electrode. Accordingly, by reducing this distance, it is possible to manufacture an FET having a threshold voltage 0 V or higher, that is, a normally-off FET. By arbitrarily forming an oxygen-doped region, it is possible to arbitrarily set the distance between the channel and the lower part of the gate electrode without variation; thus, the present invention is effective for manufacturing the normally-off FET without variation in threshold voltage.

Note that the present invention is not limited to the embodiments described above, but various modifications and variations are possible within the scope of the present invention without departing from the novel teaching and advantages of the present invention.

For example, the GaAs layer that is to be the channel layer may also be a stacking structure of InGaAs and GaAs layers, and may also include an AlGaAs layer.

In addition, although Si has been assumed as the impurity for providing n-type characteristics to the n-type AlₓGa₁₋ₓAs layer in the embodiments above, another impurity may be used. In addition, in the embodiments above, although the concentration of the impurity has been assumed as 1×10¹⁸ cm⁻³, such concentration is not limited to this, and may vary in a layer thickness direction.

In addition, in the embodiments described above, although the AlGaAs layer has been described as an example of the barrier layer, the barrier layer is not limited to this, and may be another layer such as an InGaP layer or an InAlAs layer having a larger bandgap than the GaAs layer.

In addition, the semiconductor transistor according to an implementation of the present invention includes: another embodiment realized by a combination of arbitrary constituent elements in the embodiments described above; variations obtained through any variation conceived by those skilled in the art without materially departing from the scope of the present invention, and various types of devices including the semiconductor transistor according to the present invention. Accordingly all such modifications are intended to be included within the scope of the present invention. In the first and the second embodiments described above, the device including a single FET has been described as an example, but the present invention is also applicable to another semiconductor device including an FET, such as a Bi-FET including an FET and a HBT that are formed on a single substrate.

### INDUSTRIAL APPLICABILITY

A semiconductor transistor according to the present invention is applicable to, for example, a heterojunction field-effect transistor using GaAs. Particularly, the technique is applicable to an RF device used for a cellular phone or the like.

What is claimed is:

1. A semiconductor transistor comprising:
a substrate;
a first compound semiconductor layer formed above said substrate;
a second compound semiconductor layer formed on said first compound semiconductor layer and having a bandgap larger than a bandgap of said first compound semiconductor layer;
an oxygen-doped region formed by doping at least part of said second compound semiconductor layer with oxygen;
a third compound semiconductor layer formed on said second compound semiconductor layer;
a source electrode electrically connected to said first compound semiconductor layer;
a drain electrode electrically connected to said first compound semiconductor layer; and
a gate electrode formed on and in contact with said oxygen-doped region.

2. The semiconductor transistor according to claim 1,
wherein said source electrode and said drain electrode are formed on said third compound semiconductor layer,
said second compound semiconductor layer and said third compound semiconductor layer include, under said source electrode and said drain electrode, a low resistance region to which an impurity is added, and
said source electrode and said drain electrode are electrically connected to said first compound semiconductor layer via said low resistance region.

3. The semiconductor transistor according to claim 1,
wherein said second compound semiconductor layer and said third compound semiconductor layer include a recess formed to reach at least said second compound semiconductor layer from a surface of said third compound semiconductor layer, and
said source electrode and said drain electrode are formed in contact with at least one of a bottom surface and a lateral surface of said recess.

4. The semiconductor transistor according to claim 1,
wherein said second compound semiconductor layer includes AlₓGa₁₋ₓAs (0<x≦1).

5. The semiconductor transistor according to claim 1,
wherein said oxygen-doped region has a thickness of 5 nm or less.

6. The semiconductor transistor according to claim 1,
wherein said oxygen-doped region is a semiconductor layer. 15

7. The semiconductor transistor according to claim 1,
wherein a concentration of oxygen introduced into said oxygen-doped region is 5×10¹⁶ cm⁻³ or more.

8. The semiconductor transistor according to claim 1,
wherein said gate electrode includes, at least partially, Pt or Pd.

9. A method of manufacturing a semiconductor transistor, comprising:
forming, above a substrate, a first compound semiconductor layer and a second compound semiconductor layer that has a bandgap larger than a bandgap of said first compound semiconductor layer;
forming an oxygen-doped region by doping at least part of the second compound semiconductor layer with oxygen;
forming a third compound semiconductor layer on the second compound semiconductor layer;
forming a source electrode and a drain electrode that are electrically connected to the first compound semiconductor layer;
forming a gate electrode on a surface of the third compound semiconductor layer located on the oxygen-doped region; and
diffusing, into the third compound semiconductor layer, a material for forming the gate electrode.

10. The method of manufacturing a semiconductor transistor according to claim 9, said method further comprising
forming a low resistance region to which an impurity is added, prior to said forming of a source electrode and a drain electrode, in the second compound semiconductor layer and the third compound semiconductor layer, under a position at which each of the source electrode and the drain electrode is formed.

11. The method of manufacturing a semiconductor transistor according to claim 9, said method further comprising
forming a recess, prior to said forming of a source electrode and a drain electrode, below a position at which each of the source electrode and the drain electrode is formed, the recess reaching at least the second compound semiconductor layer from a surface of the third compound semiconductor.
